(19) United States
(12) Patent Application Publication
(10) Pub. No.: US 2020/0224918 A1
(43) Pub. Date: Jul. 16, 2020

(54) POWER SUPPLIES FOR THERMOSTATS IN HVAC SYSTEMS

(71) Applicant: EMERSON ELECTRIC CO., St. Louis, MO (US)

(72) Inventor: Esan Alhilo, Florissant, MO (US)

(21) Appl. No.: 16/358,611

(22) Filed: Mar. 19, 2019

Related U.S. Application Data
(60) Provisional application No. 62/790,789, filed on Jan. 10, 2019.

(51) Int. Cl. F24F 11/88; G05F 1/62; H02M 7/219; H02J 7/02; G01R 31/3835; F24F 11/56

(52) U.S. Cl. CPC F24F 11/88; G05F 1/62; F24F 11/56; H02J 7/025; G01R 31/3835; H02M 7/219

(57) ABSTRACT

A power supply for a thermostat in an HVAC system includes a rectifier having a rectifier input for receiving input power from a voltage source, and a rectifier output. The thermostat also includes a rechargeable battery having a battery output, a voltage regulator coupled to receive a voltage from the rectifier output, and a boost regulator including a boost regulator input. The boost regulator is configured to convert a voltage received at the boost regulator input from the voltage regulator or the battery output. The thermostat also includes a battery charger management circuit configured to monitor a battery charge state of the rechargeable battery, and to selectively charge the rechargeable battery according to an operation state of the thermostat. Example methods of operating a power supply for a thermostat in an HVAC system are also disclosed.

### CROSS-REFERENCE TO RELATED APPLICATION

This application claims the benefit and priority of U.S. Provisional Application No. 62/790,789 filed Jan. 10, 2019, which is incorporated herein by reference in its entirety.

### FIELD

The present disclosure generally relates to power supplies for thermostats in HVAC systems.

### BACKGROUND

This section provides background information related to the present disclosure which is not necessarily prior art.

In an HVAC system, a wireless communication thermostat typically requires higher power consumption to operate as compared to non-communicating thermostats. Power availability for such high-power thermostats may be limited if a common wire C is not available (e.g., a 4-wire HVAC system, etc.), or if the HVAC system is a hear only or a cool only HVAC system (e.g., a 2-wire system, etc.).

### DRAWINGS

The drawings described herein are for illustrative purposes only of selected embodiments and not all possible implementations, and are not intended to limit the scope of the present disclosure.

FIG. 1 is a block diagram of a power supply in a thermostat for an HVAC system according to one example embodiment of the present disclosure;

FIG. 2 is a schematic wiring diagram of a power supply in a thermostat according to another example embodiment of the present disclosure;

FIG. 3 is a schematic wiring diagram of a power-stealing circuit for a thermostat according to yet another example embodiment of the present disclosure;

FIG. 4 is a schematic wiring diagram of a battery charging circuit for a thermostat according to a further example embodiment of the present disclosure; and

FIG. 5 is schematic wiring diagram of a power supply in a thermostat according to another example embodiment of the present disclosure.

Corresponding reference numerals indicate corresponding (although not necessarily identical) parts throughout the several views of the drawings.

### DETAILED DESCRIPTION

Example embodiments will now be described more fully with reference to the accompanying drawings.

In an HVAC system, a wireless communication thermostat typically requires higher power consumption to operate as compared to non-communicating thermostats. Power availability for such high-power thermostats may be limited if a common wire C is riot available (e.g., a 4-wire HVAC system, etc.), or if the HVAC system is a heat only or a cool only HVAC system (e.g., a 2-wire system, etc.).

Disclosed herein are exemplary embodiments of power supplies for thermostats that may be connected to 2-wire HVAC systems, 4-wire HVAC systems, etc., and include at least one rechargeable battery. The thermostats can supply power from the rechargeable battery when an AC load is on, and recharge the rechargeable battery when an AC load is off, thereby extending a life of the rechargeable battery.

One or more capacitors (e.g., super capacitors, etc.) may power a thermostat during a call (e.g., a heating call, a cooling call, etc.). If a voltage on the capacitor(s) falls below a voltage of the rechargeable battery, the rechargeable battery can supply power for the thermostat. During the call, a power-stealing circuit may be disabled. Once the call is finished (e.g., a load is off), the power-stealing circuit can recharge the capacitor(s) and the rechargeable battery (e.g., recharge the capacitor(s) before recharging the rechargeable battery, etc.).

In some example embodiments, a thermostat may operate without a common C wire (e.g., during on modes and during off modes), in a 2-wire HVAC system, in a 4-wire HVAC system, etc. The thermostat may include a rectifier (e.g., a half-bridge rectifier, a full-bridge rectifier), etc. The rectifier can be connected across one or both of an AC load Y supply and an AC load W supply, to steal power during AC wave cycles. For example, the rectifier can steal power from a negative AC wave cycle, steal limited power from a positive AC wave cycle, etc.

The power-stealing circuit may steal power to charge a super capacitor, charge a rechargeable battery, provide power to a load or other circuit, etc. For example, the power-stealing circuit could steal power during both on and off modes of the thermostat, during only on or only off modes of the thermostat, etc.

A voltage regulator (e.g., a step-down voltage regulator, etc.) may convert an input voltage to a fixed output (e.g., about five VDC, etc.). An output of the voltage regulator can be selectively supplied to a battery charger circuit and/or a booster circuit of the thermostat.

The battery charger circuit can receive input power from the voltage regulator (e.g., at about five VDC, etc.), and supply output power to a rechargeable battery of the thermostat. For example, the battery charger circuit may be connected with battery terminals (e.g., Bat+, Bat−, etc.) of the rechargeable battery.

The battery charger circuit can monitor and charge the voltage of the rechargeable battery to within a specified range (e.g., about three volts to about 4.2 volts, etc.). In some embodiments, the charge current is limited to a specified charge current threshold, such as a maximum of about 500 mA, etc.

The rechargeable battery may include any suitable battery arrangement, such as a single cell lithium-ion battery, etc. In some cases, the rechargeable battery may have a capacity value of at least 500 mAh, at least 800 mAh, at least 1100 mAh, etc. Terminals of the battery can be connected to the booster circuit of the thermostat, in order to supply power to the booster circuit when power from the voltage regulator is not sufficient for thermostat operation, etc.

The booster circuit (e.g., boost regulator, etc.) can convert an output voltage from the voltage regulator and/or the rechargeable battery, to a suitable operating voltage for other components of the thermostat. For example, the booster circuit may convert an input voltage in a range of about 1.8 VDC to about 4.2 VDC, to a specified output voltage of about 3.3 VDC, etc. When the input voltage is higher than the specified output voltage, the booster circuit may perform a down conversion of the input voltage.

In some embodiments, a switching element may be coupled between an input of the booster circuit, an output of the rechargeable battery and an output of the voltage regulator. The switching element can selectively connect the booster circuit to the rechargeable battery or the voltage regulator, depending on an output voltage of the regulator and an operating state of the thermostat. The switching element may include any suitable switch, such as a MOSFET transistor, etc.

The thermostat may include a battery charger management circuit (e.g., a power management unit (PMU), etc.), that monitors the output of the rechargeable battery. In some cases, the PMU may receive power from an output of a buck circuit. The battery charger management circuit can dynamically start or stop (e.g., enable or disable) charging of the battery, which may depend on a current operating state of the thermostat.

For example, the PMU charging circuit can be disabled when the thermostat is operating on battery only, when the thermostat is operating in a 2-wire HVAC system, etc. In some cases, the charge current may be limited to a power-stealing capability of the thermostat.

In some embodiments, the thermostat may be connected to a wireless network device, such as a Wi-Fi router, a remote server via a cloud network connection, etc. When idle, the thermostat may experience an average idle current consumption value, such as about four mA, etc. In that case, any power received by the thermostat above the average idle current consumption value (e.g., above four mA, etc.) could be utilized to charge the rechargeable battery as needed.

As described above, the voltage regulator can supply power to both the thermostat and the battery charger for the rechargeable battery. If a demand of the thermostat exceeds a power supplied by the voltage regulator, the voltage regulator may turn off and allow the rechargeable battery to supply power to the thermostat (e.g., via the booster circuit, etc.).

During power-stealing operation in a 4-wire HVAC system when one of the AC loads is on, a power supply of the thermostat use a full bridge rectifier coupled to an AC load that is off to steal power for the voltage regulator (e.g., to supply power to the thermostat and recharge the rechargeable battery, etc.). When both AC loads are off in the 4-wire HVAC system, the power supply can use full bridge rectifiers for each load to steal power for the voltage regulator.

In a 2-wire HVAC system when the AC load is on, the power supply may operate with power from the rechargeable battery only. In this case, the thermostat may not steal power from the 2-wire HVAC system, the power supply may not charge the battery, etc. An output power capability of the power supply may be limited, and the thermostat may operate in a deep sleep mode with limited user interface functionality. The power supply may include an intrinsic time element based on a charge status of the battery. When the AC load is off in the 2-wire HVAC system, the power supply can use the full bridge rectifier to steal power for the voltage regulator.

In some embodiments, the thermostat may implement low battery management if a voltage of the rechargeable battery drops below a specified threshold. For example, if the voltage of the rechargeable battery drops below a lower specified threshold (e.g., about 3.0 V, etc.) the thermostat may disconnect from a Wi-Fi router and cloud network connection until the voltage of the rechargeable battery increases to at least an upper specified threshold (e.g., about 3.45 V, etc.), the thermostat may turn off an AC load until the voltage of the rechargeable battery increases to at least the upper specified threshold (e.g., about 3.45 V, etc.), etc.

Specific voltage and other parameter values are described herein for purposes of illustration only, and other appropriate values may be used without departing from the scope of the present disclosure. In some cases, specified values may be approximate within a tolerance range of +/−1%, +/−5%, +/−10%, etc.

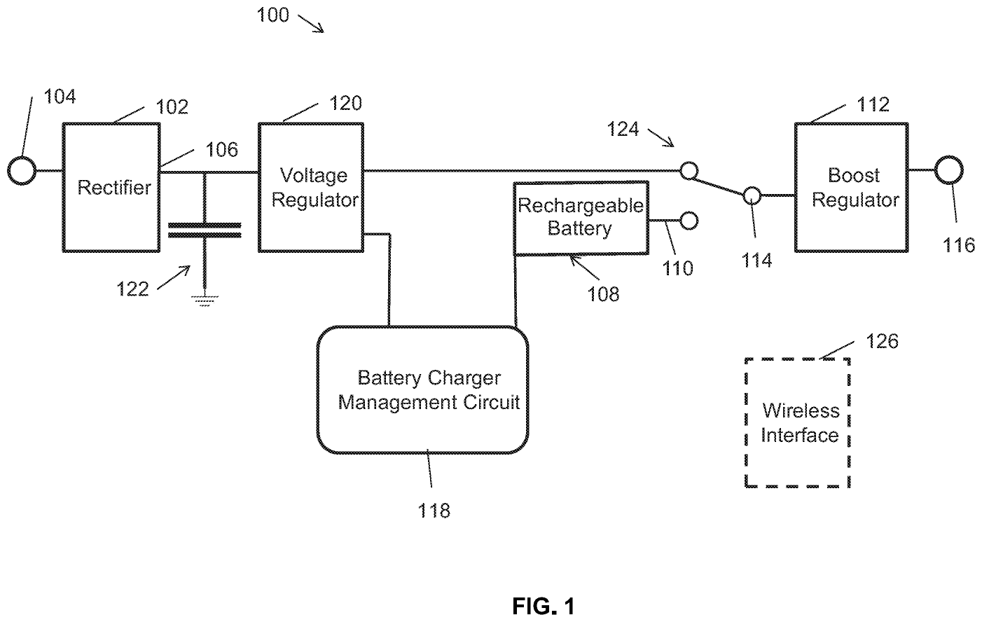

With reference to the figures, FIG. 1 illustrates a power supply 100 for a thermostat in an HVAC system, according to one example embodiment of the present disclosure. As shown in FIG. 1, the power supply 100 includes a rectifier 102. The rectifier 102 has a rectifier input 104 for receiving alternating current (AC) input power from a voltage source. The rectifier 102 also has a rectifier output 106 for supplying direct current (DC) power to other components of the power supply 100.

The power supply 100 includes a rechargeable battery 108 having a battery output 110, a voltage regulator 120 and a boost regulator 112 having a boost regulator input 114. The boost regulator 112 is configured to convert a voltage received at the boost regulator input 114 from an output of a voltage regulator 120 or the battery output 110, and supply an output voltage at a boost regulator output 116.

The power supply 100 further includes a battery charger management circuit 118 configured to monitor a battery charge state of the rechargeable battery 108, and to selectively charge the rechargeable battery 108 according to the operation state of the thermostat.

As shown in FIG. 1, the voltage regulator 120 is coupled to receive a voltage from the rectifier output 106. The voltage regulator 120 may supply power to the boost regulator 112, to the rechargeable battery 108, etc.

A capacitor 122 may be coupled between the voltage regulator 120 and the rectifier output 106. The capacitor 122 can store a charge for supplying power to other components in the power supply 100 (e.g., when power received at the rectifier input 104 is not sufficient, etc.). The capacitor 122 may include one or more capacitors, which may have any suitable capacitance value(s), such as 440 uF, etc.

The battery charger management circuit 118 is coupled between the voltage regulator 120 and the rechargeable battery 108 to supply power to the rechargeable battery 108. As described above, the battery charger management circuit 118 can monitor a charge state of the rechargeable battery 108, and selectively charge the rechargeable battery 108 according to the operation state of the thermostat.

The rechargeable battery 108 may include one or more rechargeable batteries, which can include any suitable battery construction. For example, the rechargeable battery 108 may include a lithium-ion battery, etc. The rechargeable battery 108 can have any suitable capacity, such as at least 500 mAh, at least 800 mAh, 1100 mAh, etc.

As shown in FIG. 1, a switch 124 is coupled between the input 114 of the boost regulator 112, the output of the voltage regulator 120, and the battery output 110. The switch 124 can selectively connect the boost regulator 112 to receive power from the voltage regulator 120 and/or the rechargeable battery 108. The switch 124 may change the connection according to a current operation state of the thermostat, as described further below.

The thermostat includes an optional wireless interface 126. The wireless interface may communicate wirelessly with a remote network access point, such as a WiFi router, a cloud network device, etc. Alternatively, or in addition, the thermostat may include one or more wired communication connections, other wireless interfaces, etc.

In some embodiments, the wireless interface 126 is configured to disconnect from the remote network access point and change a set point to turn off an AC load, when a voltage of the rechargeable battery 108 is below a specified charge threshold.

For example, a specified charge threshold may be in a range between about 3.0 V and 4.2 V. In this case, if the voltage of the rechargeable battery 108 drops below about 3.0 V, the thermostat may disconnect from a Wi-Fi router and cloud network connection until the voltage of the rechargeable battery 108 increases to at least about 3.45 V. Additionally, or alternatively, the thermostat may turn off an AC load until a voltage of the rechargeable battery 108 increases to at least about 3.45 V. For example, the thermostat may enter a hold mode heat set point of about 62 degrees Fahrenheit and a cool set point of about 85 degrees Fahrenheit until a voltage of the rechargeable battery is at least 3.45 V. In other embodiments, other suitable voltage thresholds, temperature set points, etc., may be used.

The power supply 100 may operate with varying levels of power consumption, current, etc., which may depend on a current operation state of the thermostat (e.g., a boot-up mode, a normal operation mode, a sleep mode, etc.), whether the wireless interface 126 is enabled, whether a display light of the thermostat is on, etc.

For example, the thermostat may operate with about 115 mA of current, about 184 mA, about 190 mA, about 262 mA, about 310 mA, about 340 mA, etc., depending on the factors described above. In some cases, the wireless interface 126 may include a power-saving mode that can reduce operating current by about 48 mA, etc. The rechargeable battery 108 may charge with a current of about 95 mA, etc. As should be apparent, other embodiments may use other suitable currents.

The rectifier input 104 may include any suitable terminals, connectors, wire traces, etc., for connecting to an HVAC system. For example, the rectifier input 104 may include two input connections adapted to electrically connect with a 2-wire HVAC system, the rectifier input 104 may include four input connections adapted to electrically connect with a 4-wire HVAC system that does not include a common C wire, etc.

When connected to a 2-wire HVAC system, the battery charger management circuit 118 may be configured to disable charging of the rechargeable battery 108 when the operation state of the thermostat is “currently operating.” The battery charge management circuit 118 can also be configured to enable charging of the rechargeable battery 108 when the operation state of the thermostat is “not currently operating.”

When connected to a 4-wire HVAC system without a common C wire connection, the battery charger management circuit 118 may be configured to disable charging of the rechargeable battery 108 when the operation state of the thermostat is “operating on battery only.” The battery charger management circuit 118 can also be configured to enable charging of the rechargeable battery 108 when the operation state of the thermostat includes “less than two AC loads currently operating.”

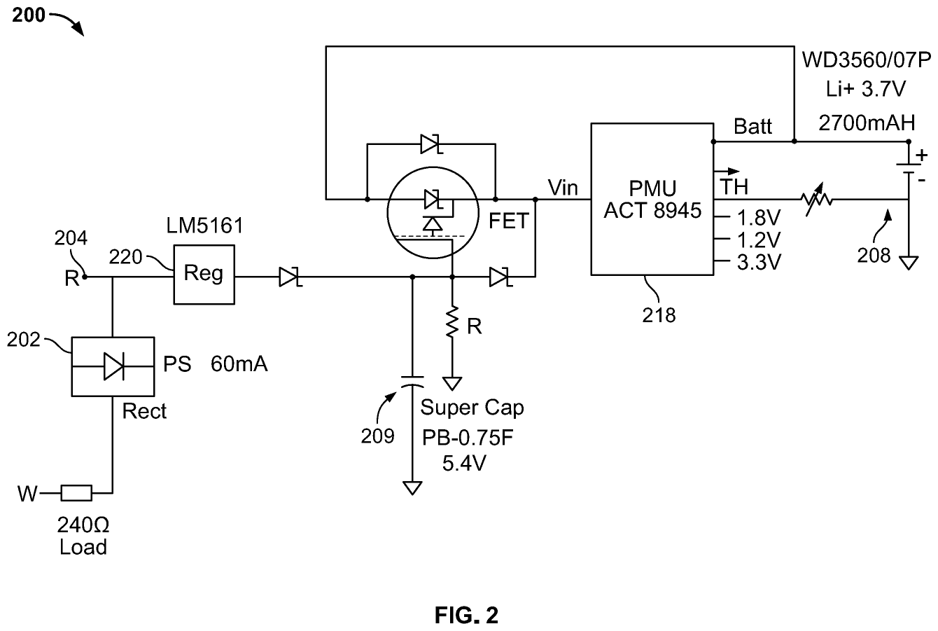

FIG. 2 illustrates a power supply 200 in a thermostat according to another example embodiment of the present disclosure. As shown in FIG. 2, the power supply 200 includes a rectifier 202 having a rectifier input 204 for connection to a 2-wire HVAC system (e.g., R and W wires for heat, R and Y wires for cool, etc.).

In some embodiments, the rectifier 202 may be a power-stealing circuit for stealing power from the 2-wire HVAC system. For example, the rectifier 202 may ‘steal’ power from the 2-wire HVAC system that is above a specified voltage threshold, above a specified current threshold, etc., to supply power to components of the thermostat.

In some cases, the rectifier 202 may steal power from a connected system. For example, depending on the connected system, the rectifier 202 may supply current up to a specified threshold, such as 60 mA, 65 mA, etc. Additionally, or alternatively, the thermostat may receive power from a solar panel (e.g., at a voltage of about five volts and a current of about 230 mA, etc.), the thermostat may receive power from a lithium battery (e.g., at a voltage of about 2.7 A), etc.

A voltage regulator 220 is coupled to receive power from the rectifier 202. The voltage regulator 220 may charge a super capacitor 209. A power management unit (PMU) 218 (e.g., a battery charger circuit), is configured to monitor a rechargeable battery 208, to selectively charge the rechargeable battery 208, to supply power to other components in the thermostat, etc.

Example component values are included in FIG. 2 for purposes of illustration only, and other embodiments may use different values without departing from the scope of the present disclosure.

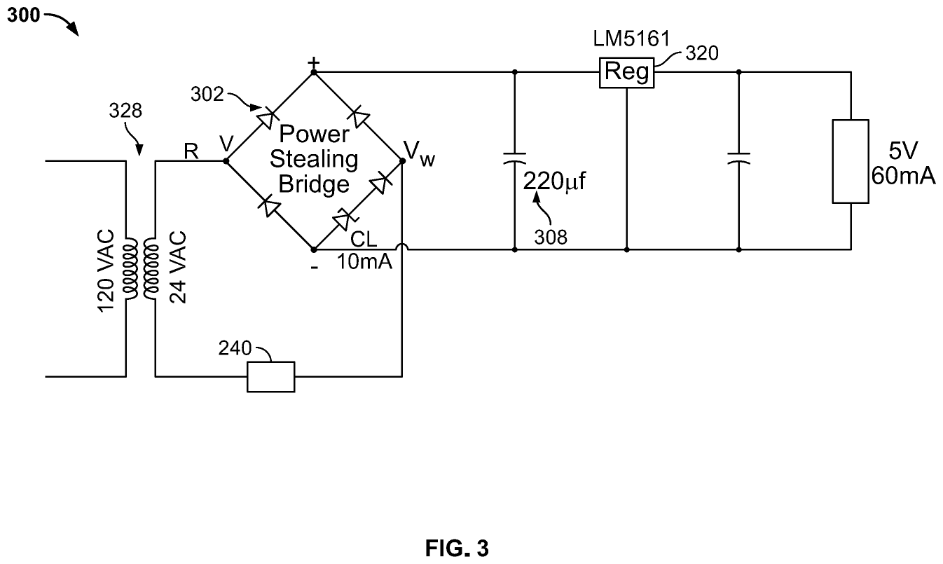

FIG. 3 illustrates a ‘power-stealing’ circuit 300 according to another example embodiment of the present disclosure. As shown in FIG. 3, the circuit 300 includes a rectifier 302. The rectifier 302 is coupled to receive power from a transformer 328 (e.g., a 120 VAC to 24 VAC transformer, etc.) via the connected heat or cool system load.

The circuit 300 also includes a voltage regulator 320, and a capacitor 308 (e.g. having a capacitance value of about 440 uF, etc.) coupled between the voltage regulator 320 and the rectifier 302. The capacitor 308 can store a charge received from the rectifier 302, and the voltage regulator is configured to supply output power to other components in the thermostat.

Example component values are included in FIG. 3 for purposes of illustration only, and other embodiments may use different values without departing from the scope of the present disclosure.

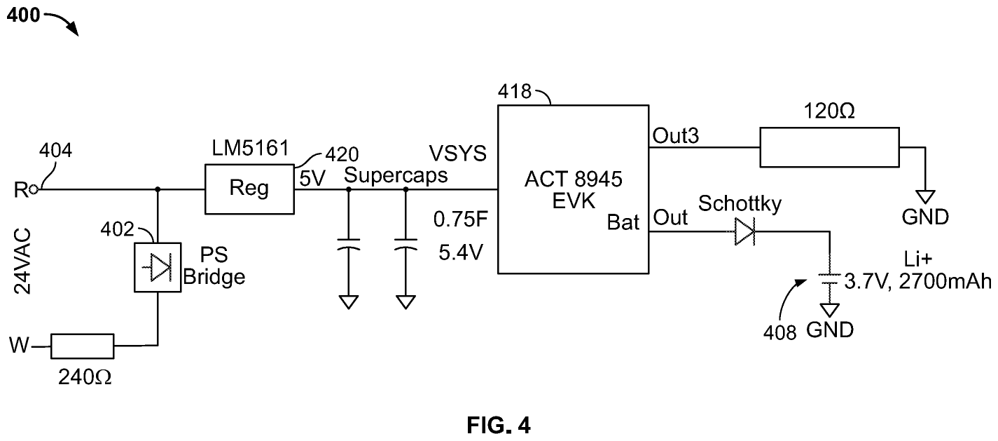

FIG. 4 illustrates a battery charging circuit 400 according to another example embodiment of the present disclosure. As shown in FIG. 4, the battery charging circuit 400 includes a rectifier 402 having a rectifier input 404 for connection to a 2-wire HVAC system (e.g., R and W wires for heat, R and Y wires for cool, etc.).

In some embodiments, the rectifier 402 may be a power-stealing circuit for stealing power from the 2-wire HVAC system. For example, the rectifier 402 may ‘steal’ power from the 2-wire HVAC system that is above a specified voltage threshold, above a specified current threshold, etc., to supply power to components of a thermostat, etc.

A voltage regulator 420 is coupled to receive power from the rectifier 402. The voltage regulator 420 supplies power to the battery charger circuit 418 (e.g., a PMU ACT8945, etc.), charges the super capacitors, etc. A battery charger circuit 418 is configured to monitor a rechargeable battery 408, to selectively charge the rechargeable battery 408, to supply power to other thermostat circuits, etc.

Example component values are included in FIG. 4 for purposes of illustration only, and other embodiments may use different values without departing from the scope of the present disclosure.

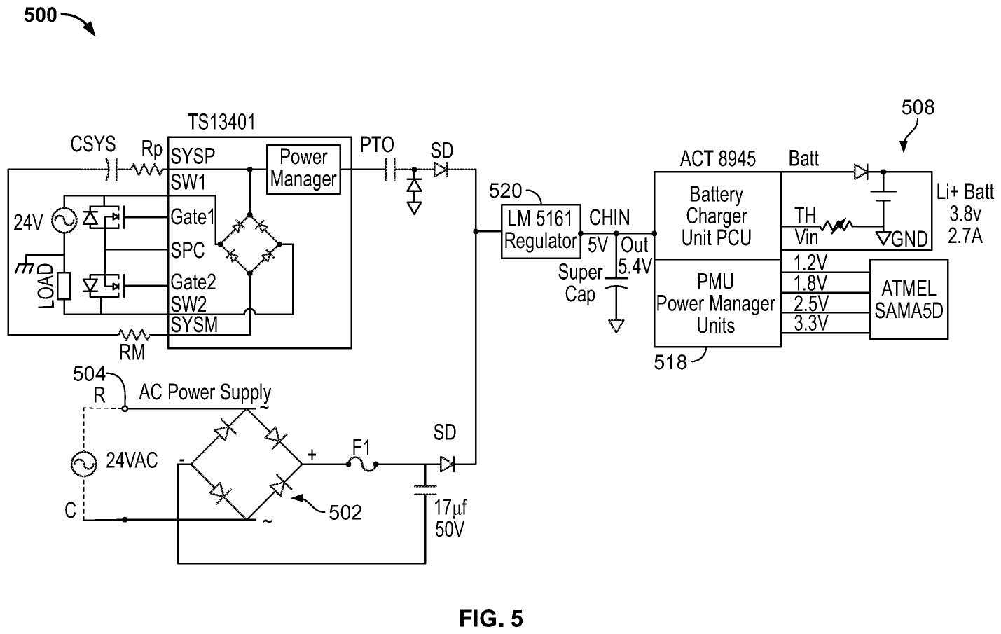

FIG. 5 illustrates a power supply 500 for a thermostat according to another example embodiment of the present disclosure. As shown in FIG. 5, the power supply 500 includes a rectifier 502 having a rectifier input 504 for connection to an AC power supply (e.g., R and C wires of an HVAC system with a common wire, etc.).

A voltage regulator 520 is coupled to receive power from the rectifier 502. A battery charger circuit 518 is configured to monitor a rechargeable battery 508, and to selectively charge the rechargeable battery 508. The component TS13401 is a MOSFET driver designed to steal power when the system is on and when the system is off, when the common wire is not available for two and four wire systems. A power transfer output (PTO) of the component TS13401 is coupled with an input of the voltage regulator 520.

Example component values are included in FIG. 5 for purposes of illustration only, and other embodiments may use different values without departing from the scope of the present disclosure.

According to another example embodiment of the present disclosure, a method of operating a thermostat in an HVAC system is disclosed. The thermostat includes a rectifier having a rectifier output, a rechargeable battery including a battery output, a voltage regulator coupled to receive a voltage from the rectifier output, a boost regulator including a boost regulator input, and a battery charger management circuit.

The method includes converting, by the boost regulator, a voltage received at the boost regulator input from the voltage regulator or the battery output, and monitoring, by the battery charger management circuit, an operation state of the thermostat. The method also includes selectively charging the rechargeable battery according to an operation state of the thermostat.

In some embodiments, the thermostat includes a wireless interface configured to communicate data wirelessly with a remote network access point. In that case, the method may include disconnecting the wireless interface from the remote network access point and changing and holding set points to specified values (e.g., about 62 degrees Fahrenheit for heat, about 85 degrees Fahrenheit for cool, etc.), to turn off an AC load, when a voltage of the rechargeable battery is below a specified charge threshold.

When the rectifier input includes two input connections adapted to electrically connect with a 2-wire HVAC system, the method may include disabling charging of the rechargeable battery when the operation state of the thermostat is currently operating, and enabling charging of the rechargeable battery when the operation state of the thermostat is not currently operating.

In some embodiments, the rectifier input may include four input connections adapted to electrically connect with a 4-wire HVAC system that does not include a common C wire. In that case, the method may include disabling charging of the rechargeable battery when the operation state of the thermostat is operating on battery only. Additionally, or alternatively, the method can include enabling charging of the rechargeable battery when the operation state of the thermostat includes less than two AC loads currently operating.

Example thermostats and components described herein may be configured to perform operations using any suitable combination of hardware and software. For example, the thermostats and components may include any suitable circuitry, logic gates, processor(s), computer-executable instructions stored in memory, etc., operable to cause the thermostats and components to perform actions described herein (e.g., enabling and disabling charging of a rechargeable battery, etc.).

Example thermostats described herein may provide one or more (or none) of the following advantages: the ability for a thermostat (e.g., a wired or wireless communicating thermostat, etc.) to connect to a 2-wire HVAC system, using a rechargeable battery when an AC load of the thermostat is on, recharging the rechargeable battery when the AC load is off, extending a battery life of the rechargeable battery, allowing for a power-stealing circuit to supply power to the thermostat from a 4-wire system without a common wire, etc.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and3-9.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally,” “about,” and “substantially,” may be used herein to mean within manufacturing tolerances. Whether or not modified by the term “about,” the claims include equivalents to the quantities.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A power supply for a thermostat in an HVAC system, the power supply comprising:
a rectifier including a rectifier input for receiving input power from an AC voltage source, and a rectifier output;
a rechargeable battery including a battery output;
a voltage regulator coupled to receive a voltage from the rectifier output;
a boost regulator including a boost regulator input, the boost regulator configured to convert a voltage received at the boost regulator input from the voltage regulator or the battery output; and
a battery charger management circuit configured to monitor a battery charge state of the rechargeable battery, and to selectively charge the rechargeable battery according to an operation state of the thermostat.

2. The power supply of claim 1, wherein the voltage regulator includes a voltage regulator output coupled to supply power to the boost regulator or the battery charger management circuit.

3. The power supply of claim 2, further comprising a capacitor coupled between the voltage regulator and the rectifier output.

4. The power supply of claim 3, wherein the capacitor has a capacitance value of at least 440 uF.

5. The power supply of claim 2, wherein the battery charger management circuit is coupled between the voltage regulator and the rechargeable battery to supply power to the rechargeable battery.

6. The power supply of claim 5, further comprising a switch configured to selectively connect the boost regulator input with the voltage regulator output or the battery output.

7. The power supply of claim 1, wherein the rechargeable battery includes a lithium-ion battery having a capacity value of at least 800 mAh.

8. The power supply of claim 1, wherein the thermostat includes a wireless interface configured to communicate data wirelessly with a remote network access point.

9. The power supply of claim 8, wherein the wireless interface is configured to disconnect from the remote network access point and change and hold at least one set point to a specified value to turn off an AC load, when a voltage of the rechargeable battery is below a specified charge threshold.

10. The power supply of claim 9, wherein the specified charge threshold is in a range between 3.0 V and 4.2 V.

11. The power supply of claim 1, wherein the rectifier input includes two input connections adapted to electrically connect with a 2-wire HVAC system.

12. The power supply of claim 11, wherein the battery charger management circuit is configured to disable charging of the rechargeable battery when the operation state of the thermostat is currently operating, and to enable charging of the rechargeable battery when the operation state of the thermostat is not currently operating.

13. The power supply of claim 1, wherein the rectifier input includes four input connections adapted to electrically connect with a 4-wire HVAC system that does not include a common C wire.

14. The power supply of claim 13, wherein the battery charger management circuit is configured to disable charging of the rechargeable battery when the operation state of the thermostat is operating on battery only.

15. The power supply of claim 13, wherein the battery charger management circuit is configured to enable charging of the rechargeable battery when the operation state of the thermostat includes less than two AC loads currently operating.

16. A method of operating a power supply in a thermostat for an HVAC system, the thermostat including a rectifier including a rectifier output, a rechargeable battery including a battery output, a voltage regulator coupled to receive a voltage from the rectifier output, a boost regulator including a boost regulator input, and a battery charger management circuit, the method comprising:
converting, by the boost regulator, a voltage received at the boost regulator input from the voltage regulator or the battery output;
monitoring, by the battery charger management circuit, a battery charge state of the rechargeable battery; and
selectively charging the rechargeable battery according to an operation state of the thermostat.

17. The method of claim 16, wherein the thermostat includes a wireless interface configured to communicate data wirelessly with a remote network access point, the method further comprising disconnecting the wireless interface from the remote network access point and changing and holding at least one set point to a specified value to turn off an AC load, when a voltage of the rechargeable battery is below a specified charge threshold.

18. The method of claim 16, wherein the rectifier input includes two input connections adapted to electrically connect with a 2-wire HVAC system, the method further comprising:
disabling charging of the rechargeable battery when the operation state of the thermostat is currently operating; and
enabling charging of the rechargeable battery when the operation state of the thermostat is not currently operating.

19. The method of claim 16, wherein the rectifier input includes four input connections adapted to electrically connect with a 4-wire HVAC system that does not include a common C wire, the method further comprising disabling charging of the rechargeable battery when the operation state of the thermostat is operating on battery only.

20. The method of claim 16, wherein the rectifier input includes four input connections adapted to electrically connect with a 4-wire HVAC system that does not include a common C wire, the method further comprising enabling charging of the rechargeable battery when the operation state of the thermostat includes less than two AC loads currently operating.
